(19) United States
(12) Patent Application Publication
(10) Pub. No.: US 2022/0297078 A1
(43) Pub. Date: Sep. 22, 2022

(54) SONOCHEMICAL SYNTHESIS OF PARTICLES

(71) Applicant: UNIVERSITY OF WASHINGTON, Seattle, WA (US)

(72) Inventors: Lilo D. Pozzo, Seattle, WA (US); Ryan Kastilani, Seattle, WA (US); Brittany P. Bishop, Seattle, WA (US); David Shicheng Li, Seattle, WA (US)

(21) Appl. No.: 17/633,890

(22) PCT Filed: Aug. 6, 2020
(86) PCT No.: PCT/US2020/045222

§ 371 Date: Feb. 8, 2022

Related U.S. Application Data
(60) Provisional application No. 62/884,648, filed on Aug. 8, 2019.

(51) Int. Cl. B01J 19/10; B01J 19/06; C01B 19/00; C09K 11/88

(52) U.S. Cl. CPC B01J 19/10; B01J 19/06; C01B 19/007; C09K 11/883; C01P 2004/62; C01P 2002/72; C01P 2004/02; B01J 2219/0888

(57) ABSTRACT

Sonochemical synthesis methods of particles (e.g., nanoparticles, microparticles, quantum dots) in emulsion reaction mixtures are described herein. The methods allow for control of the bulk temperature of the reaction mixtures to minimize the effects of solvent temperature increases. The sonochemical synthesis methods (e.g., in emulsion reaction mixtures) offer efficient, accelerated, and controllable pathways towards the on-demand synthesis of complex materials.

### CROSS-REFERENCE TO RELATED APPLICATION

This application claims the benefit of U.S. Patent Application No. 62/884,648, filed Aug. 8, 2019, the disclosure of which is hereby incorporated by references in its entirety.

### STATEMENT OF GOVERNMENT LICENSE RIGHTS

This invention was made with government support under Grant No. DMR 1719797, awarded by the National Science Foundation. The government has certain rights in the invention.

### BACKGROUND

Over the past decades, there has been great interest in the synthesis and application of semiconductor quantum dots (QD) because they exhibit properties that are drastically different from that of their bulk counterparts due to the effects of quantum confinement. In short, the effect of quantum confinement is observed when the exciton diameter is less than at least one of the dimensions of the particle, leading to unique optical and electronic properties, which are tunable by the size, shape, and composition of the QD particles. Due to their unique properties, QDs find numerous applications including bio-labelling/imaging, electronic, and optical devices. A subset of QDs are magic-size clusters (MSC), tiny QDs that are typically less than 2 nm with a well-defined number of atoms. They are at the interface of molecules and QDs and themselves have unique properties. Applications and advantages of MSCs include white LEDs, renal clearance in biological imaging, and their use as starting materials for more complex nanostructures.

Traditionally, QDs are prepared by a hot-injection method, where molecular precursors are injected into a hot solvent at a few hundred degrees Celsius. This method has been successful in synthesizing nanocrystals (NC) with various sizes, shapes, and compositions. Unfortunately, this technique also has a number of critical drawbacks that make it difficult to scale and that can result in QD variability. The method relies on rapid injection of up to 50% of the total mixture volume, and mixing of the reagents at high temperature, which becomes difficult as reaction volumes become larger. After the initial injection, often the reaction temperature is decreased to control NC growth, and the cooling rate does not scale with vessel size. All of these drawbacks prevent a scaled-up and reproducible synthesis of NCs. An alternative method is the heat-up method, where all precursors are mixed initially in a vessel and heated controllably. However, this method has its own drawbacks. Decoupling of nucleation and growth is necessary to prevent polydispersity. Great care must be taken to ensure that there is sufficient nucleation within a short period of time. In the case of multicomponent QDs, it is vital to rapidly heat the mixture to a temperature where the reactivity of all components is matched, otherwise the composition of the NCs will not reflect that of the original bulk solution.

There is a need for a scalable and reproducible method for the synthesis of particles having controlled sizes, shapes, and compositions. The present disclosure fulfills these needs and provides further advantages.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In one aspect, the present disclosure features a sonochemical method of making particles, including providing an emulsion that includes uniformly dispersed immiscible droplets in a continuous phase, and one or more particle precursors; exposing the emulsion to ultrasound irradiation having a frequency of at least 20 kHz to nucleate and form particles in the emulsion, without increasing an emulsion bulk temperature by 50° C. or more; and isolating the particles from the emulsion. When the emulsion is an aqueous emulsion, the particle precursors do not include a gold salt.

In another aspect, the present disclosure features particles made according to the methods described herein.

### DESCRIPTION OF THE DRAWINGS

The foregoing aspects and many of the attendant advantages of this disclosure will become more readily appreciated as the same become better understood by reference to the following detailed description, when taken in conjunction with the accompanying drawings, wherein:

FIG. 1 is a schematic representation of an embodiment of a method of particle synthesis, together with photos of exemplary final particle products illuminated with UV light.

FIG. 2A is an absorbance plot of an embodiment of cleaned CdSe particles synthesized with sonication in the single-phase ‘bulk’ system.

FIG. 2B shows the photoluminescence (PL) spectra (λ_{exc}=360 nm) of an embodiment of cleaned CdSe particles synthesized with sonication in a single-phase ‘bulk’ system.

FIG. 3A is a SAXS profile of an embodiment of CdSe particles synthesized with sonication in bulk, before cleaning, in absolute scale.

FIG. 3B is a SAXS profile of an embodiment of CdSe particles synthesized with sonication in bulk, after cleaning, in arbitrary scale, with an inset showing the diameter of the particles extracted from model fitting.

FIG. 4A is an absorbance plot of an embodiment of cleaned CdSe particles synthesized using sonication, in emulsion systems, as a function of sonication time.

FIG. 4B shows a PL spectra (λ_{exc}=420 nm) of an embodiment of cleaned CdSe particles synthesized using sonication in emulsion systems, as a function of sonication time.

FIG. 5A is a SAXS profile of an embodiment of CdSe particles synthesized with sonication in an emulsion system, as as-prepared samples (i.e., before cleaning), in absolute scale units.

FIG. 5B is a SAXS profile for an embodiment of CdSe particles synthesized with sonication in an emulsion system, after purification, in an arbitrary intensity scale.

FIG. 6A shows an XRD spectra of an embodiment of CdSe particles synthesized with sonication in bulk. Vertical lines represent the expected peak positions for the CdSe bulk zincblende structure.

FIG. 6B shows an XRD spectra of an embodiment of CdSe particles synthesized with sonication in emulsion systems.

FIG. 7A is a micrograph showing an embodiment of CdSe particles after 180 minutes of sonication in a single-phase bulk system.

FIG. 7B is a micrograph showing an embodiment of CdSe particles after 180 minutes of sonication in a dispersed emulsion system.

FIG. 8A is an absorbance plot at 420 nm of an embodiment of MSCs from an emulsion system tracked with sonication time.

FIG. 8B is graph showing the conversion of Cd and Se precursors into (CdSe) with sonication.

FIG. 9A is a graph of quantitative absorbance at 420 nm of CdSe particles synthesized in the emulsion system with periodic 10-minute sonication on-off cycles. Shaded bands indicate the time period during which sonication is active.

FIG. 9B is a schematic representation of an embodiment of particle synthesis mechanism. Cavitation provides the energy required for precursors to chemically react, form clusters, and grow into particles.

FIG. 10A shows an ultraviolet-visible (UV-Vis) spectra, showing the growth and dissolution of an embodiment of MSCs when they do not form large aggregates.

FIG. 10B shows the UV-Vis spectra of embodiments of reaction samples from a single-phase ‘bulk’ system followed with different sonication times.

FIG. 11 is a graph showing a temperature of an embodiment of a reaction mixture tracked with sonication time.

FIG. 12 is a UV-Vis spectra of an embodiment of a reaction mixture.

FIG. 13 is a UV-Vis spectra of embodiments of reaction samples from an emulsion system before cleaning.

FIG. 14 is a graph comparing the SAXS profile of embodiments of MSCs and a model fit using a fractal model.

FIG. 15 is a graph showing the SAXS fitting of an embodiment of CdSe particles synthesized in a single-phase bulk system.

### DETAILED DESCRIPTION

The present disclosure features sonochemical synthesis methods for particles (e.g., nanoparticles, microparticles, quantum dots (QDs), MSCs) in emulsion reaction mixtures, such that the bulk temperature of the reaction mixtures minimally increases during synthesis. The sonochemical synthesis methods (e.g., in emulsion reaction mixtures) can offer efficient, accelerated, and controllable pathways towards the on-demand synthesis of complex materials, such as nanomaterials.

In the sonochemical synthesis methods of the present disclosure, ultrasound is applied to a reaction mixture containing particle precursors. When ultrasound is applied, the alternating positive and negative pressure crests can create transient vapor bubbles or cavities in the reaction mixture's liquid phase. The bubbles can oscillate and grow under continued compression and expansion cycles, gaining in potential energy. Eventually, bubbles grow to a resonant size that can lead to their abrupt and violent collapse followed by a rapid release of the accumulated energy in a very short amount of time and in a highly localized space. This results in local “hotspots with temperatures that are estimated to reach up to 5000 K and pressures in excess of 1000 bar within the bubbles. These spatially and temporally localized extreme conditions lead to rapid degradation of particle's precursor molecules that can nucleate and grow the particles.

### Definitions

It is appreciated that certain features of the disclosure, which are, for clarity, described in the context of separate embodiments, can also be provided in combination in a single embodiment.

Conversely, various features of the disclosure which are, for brevity, described in the context of a single embodiment, can also be provided separately or in any suitable subcombination.

Moreover, the inclusion of specific elements in at least some of these embodiments may be optional, wherein further embodiments may include one or more embodiments that specifically exclude one or more of these specific elements. Furthermore, while advantages associated with certain embodiments of the disclosure have been described in the context of these embodiments, other embodiments may also exhibit such advantages, and not all embodiments need necessarily exhibit such advantages to fall within the scope of the disclosure.

As used herein and unless otherwise indicated, the terms “a” and “an” are taken to mean “one”, “at least one” or “one or more”. Unless otherwise required by context, singular terms used herein shall include pluralities and plural terms shall include the singular.

Unless the context clearly requires otherwise, throughout the description and the claims, the words ‘comprise’, ‘comprising’, and the like are to be construed in an inclusive sense as opposed to an exclusive or exhaustive sense; that is to say, in the sense of “including, but not limited to.” Words using the singular or plural number also include the plural and singular number, respectively. Additionally, the words “herein,” “above,” and “below” and words of similar import, when used in this application, shall refer to this application as a whole and not to any particular portions of the application.

As used herein, the term “metal complex” refers to a metal-containing compound that includes a central metal atom or ion and a surrounding array of bound molecules or ions (i.e., ligands).

As used herein, the term “oligomer” refers to a macromolecule having 10 or less repeating units.

As used herein, the term “polymer” refers to a macromolecule having more than 10 repeating units.

As used herein, the term “substituted” or “substitution” is meant to refer to the replacing of a hydrogen atom with a substituent other than H.

As used herein, the term “alkyl” refers to a straight or branched chain fully saturated (no double or triple bonds) hydrocarbon (carbon and hydrogen only) group. Examples of alkyl groups include, but are not limited to, methyl, ethyl, propyl, isopropyl, butyl, isobutyl, sec-butyl, tertiary butyl, pentyl and hexyl. As used herein, “alkyl” includes “alkylene” groups, which refer to straight or branched fully saturated hydrocarbon groups having two rather than one open valences for bonding to other groups. Examples of alkylene groups include, but are not limited to methylene, —CH₂—, ethylene, —CH₂CH₂—, propylene, —CH₂CH₂CH₂—, n-butylene, —CH₂CH₂CH₂CH₂—, sec-butylene, and —CH₂CH₂CH(CH₃)—. An alkyl group of this disclosure may optionally be substituted with one or more fluorine groups.

As used herein, the term “alkane” refers to a to a straight or branched chain fully saturated (no double or triple bonds) hydrocarbon (carbon and hydrogen only).

As used herein, “alkenyl” refers to an alkyl group having one or more double carbon-carbon bonds. Example alkenyl groups include ethenyl (vinyl), propenyl, and the like.

As used herein, “alkene” refers to a straight or branched unsaturated hydrocarbon having one or more double carbon-carbon bonds.

As used herein, the term “aryl” refers to monocyclic or polycyclic (e.g., having 2, 3 or 4 fused rings) aromatic hydrocarbons such as, for example, phenyl, naphthyl, anthracenyl, phenanthrenyl, indanyl, and indenyl. In some embodiments, aryl groups have from 6 to about 20 carbon atoms.

As used herein, “heteroaryl” groups refer to an aromatic heterocycle having at least one heteroatom ring member such as sulfur, oxygen, or nitrogen. Heteroaryl groups include monocyclic and polycyclic (e.g., having 2, 3 or 4 fused rings) systems. Examples of heteroaryl groups include without limitation, pyridyl, pyrimidinyl, pyrazinyl, pyridazinyl, triazinyl, furyl, quinolyl, isoquinolyl, thienyl, imidazolyl, thiazolyl, indolyl, pyrryl, oxazolyl, benzofuryl, benzothienyl, benzthiazolyl, isoxazolyl, pyrazolyl, triazolyl, tetrazolyl, indazolyl, 1,2,4-thiadiazolyl, isothiazolyl, benzothienyl, purinyl, carbazolyl, benzimidazolyl, indolinyl, and the like. In some embodiments, the heteroaryl group has from 1 to about 20 carbon atoms, and in further embodiments from about 3 to about 20 15 carbon atoms. In some embodiments, the heteroaryl group contains 3 to about 14, 3 to about 7, or 5 to 6 ring-forming atoms. In some embodiments, the heteroaryl group has 1 to about 4, 1 to about 3, or 1 to 2 heteroatoms.

As used herein, the term “halo” or “halogen” includes fluoro, chloro, bromo, and iodo.

As used herein, the term “fatty acid” refers to a molecule having a carboxylic acid with a long aliphatic chain, which is either saturated or unsaturated, branched or unbranched.

As used herein, the term “fatty amine” refers to a molecule having an amino group with a long aliphatic chain, which is either saturated or unsaturated, branched or unbranched.

Unless otherwise defined, all technical and scientific terms used herein have the same meaning as commonly understood by one of ordinary skill in the art. Although methods and materials similar or equivalent to those described herein can be used in the practice or testing of the present disclosure, suitable methods and materials are described below. All publications, patent applications, patents, and other references mentioned herein are incorporated by reference in their entirety. Aspects of the disclosure can be modified, if necessary, to employ the systems, functions, and concepts of the above references and application to provide yet further embodiments of the disclosure. These and other changes can be made to the disclosure in light of the detailed description.

In case of conflict, the present specification, including definitions, will control. In addition, the materials, methods, and examples are illustrative only and not intended to be limiting.

It will be readily understood that the aspects of the present disclosure, as generally described herein, and illustrated in the figures, can be arranged, substituted, combined, separated, and designed in a wide variety of different configurations, all of which are explicitly contemplated herein.

Furthermore, the particular arrangements shown in the FIGURES should not be viewed as limiting. It should be understood that other embodiments may include more or less of each element shown in a given FIGURE. Further, some of the illustrated elements may be combined or omitted. Yet further, an example embodiment may include elements that are not illustrated in the FIGURES.

As used herein, with respect to measurements, “about” means ±5%. As used herein, a recited range includes the end points, such that from 0.5 mole percent to 99.5 mole percent includes both 0.5 mole percent and 99.5 mole percent.

The principles and conceptual aspects of various embodiments of the disclosure. In this regard, no attempt is made to show structural details of the disclosure in more detail than is necessary for the fundamental understanding of the disclosure, the description taken with the drawings and/or examples making apparent to those skilled in the art how the several forms of the disclosure may be embodied in practice.

### Methods of Synthesis

The sonochemical methods of making particles of the present disclosure include providing an emulsion that includes uniformly dispersed immiscible droplets in a continuous phase, and one or more particle precursors. The droplets and the continuous phase are immiscible with one another. The emulsion is exposed to ultrasound irradiation having a frequency of at least 20 kHz to nucleate and form particles, without increasing an emulsion bulk temperature by more than 50° C. Once the particles are formed, the particles are isolated from the emulsion. The bulk temperature of the emulsion can be measured, for example, by inserting a thermocouple or thermometer directly in the solution/dispersion, and/or by infrared imaging (i.e., bolometry). In some embodiments, when the emulsion is an aqueous emulsion, the particle precursors do not include a gold salt. In some embodiments, the emulsion is not aqueous. In some embodiments, the emulsion includes less than 50% (e.g., less than 40%, less than 30%, less than 20%, less than 10%, less than 5%, or less than 2%) by volume water. In some embodiments, the emulsion does not include an aqueous solvent.

In some embodiments, the immiscible droplets have a diameter of 10 nm or more (e.g., 50 nm or more, 100 nm or more, 200 nm or more, 500 nm or more, 1 μm or more, 25 μm or more, 50 μm or more, or 75 μm or more) and/or 100 μm or less (e.g., 75 μm or less, 50 μm or less, 25 μm or less, 1 μm or less, 500 nm or less, 200 nm or less, 100 nm or less, or 50 nm or less). For example, the immiscible droplets can have a diameter of 10 nm to 10 μm (e.g., 10 nm to 5μm, 10 nm to 1μm, or 10 nm to 500 nm). The droplet diameter can be measured by light microscopy, electron microscopy, laser light scattering, neutron or x-ray scattering, impedance measurement (e.g., with a Coulter counter), and/or acoustic measurement, at ambient temperature (e.g., 21° C.) and atmospheric pressure. Unless described otherwise, measurements in the present disclosure are conducted at ambient temperature and atmospheric pressures.

The emulsion can further include a surface stabilizer, which can be located at the interface of the immiscible droplets and the continuous phase and which can help stabilize the immiscible droplets in the continuous phase. The surface stabilizer can include, for example, oligomers, polymers, surfactants, amphiphilic molecules, particles, or any combination thereof. Non-limiting examples of polymers can include polyethylene oxide (PEO), polyethylene glycol (PEG), polypropylene oxide (PPO), polyacrylic acid (PA), poly(N-isopropylacrylamide)s (PNIPAM), hydroxypropylmethylcellulose (HPMC), and/or block-copolymers (e.g., PEO-PPO-PEO). Non-limiting examples of oligomers include those with the same repeating units as the polymers listed above. Non-limiting examples of surfactants can include anionic surfactants (e.g., alkyl sulfates), cationic surfactants (e.g., alkyl ammonium halides), non-ionic surfactants (e.g., alkyl ethoxylates, fatty acid glycerol esters), zwitterionic surfactants (e.g., sultaines, betaines), and/or lipids (e.g., phospholipids). Non-limiting examples of particle surface stabilizers include metal oxide nanoparticles (e.g., silica, titania), metal nanoparticles (e.g., gold, silver), carbon particles (e.g., graphene, carbon nanotubes), clays (e.g., mica, laponite), and/or organic nanoparticles (e.g., polystyrene latex). The particle surface stabilizers can have a diameter of 10 nm or more (e.g., 50 nm or more, 100 nm or more, 200 nm or more, 300 nm or more, or 400 nm or more) and/or 500 nm or less (e.g., 400 nm or less, 300 nm or less, 200 nm or less, 100 nm or less, or 50 nm or less).

In some embodiments, the droplets include a solvent such as terpenes (e.g., squalene), fatty acids (e.g., branched and/or linear, saturated and/or unsaturated fatty acids having 6 to 30 carbon atoms, such as oleic acid (C₁₈)); fatty amines (e.g., branched and/or linear, saturated and/or unsaturated fatty amines having 6 to 30 carbon atoms, such as oleylamine (C₁₈)); triglycerides (e.g., where each fatty acid chain, as defined above, has 6 to 30 carbon atoms); ionic liquids; deep-eutectic solvents (e.g., ethaline, glyceline); organic solvents such as alkanes (e.g., branched and/or linear alkanes having 6 to 30 carbon atoms, such as dodecane), alkenes (e.g., branched and/or linear alkenes having 6 to 30 carbon atoms, such as octadecene), and aromatic solvents (e.g., a solvent including an aryl and/or a heteroaryl group, such as toluene); silicone oils; long-chain alcohols (e.g., an alcohol having at least one hydroxyl group and 6 to 30 carbon atoms, such as dodecanol); and or perfluorocarbons (e.g., a perfluorinated hydrocarbon having 4 to 12 carbon atoms).

In some embodiments, the fatty acids include branched and/or linear, saturated and/or unsaturated fatty acids having 6 to 30 (e.g., 8 to 28, 10 to 24, 10 to 20, 10 to 18, 14 to 20, 14 to 18, 10, 12, 14, 16, 18, 20, 22, 24, 28, and/or 30) carbon atoms. In some embodiments, the fatty amines include branched and/or linear, saturated and/or unsaturated fatty amines having 6 to 30 (e.g., 8 to 28, 10 to 24, 10 to 20, 10 to 18, 14 to 20, 14 to 18, 10, 12, 14, 16, 18, 20, 22, 24, 28, and/or 30) carbon atoms. In some embodiments, the triglycerides include fatty acid chains, each having 6 to 30 (e.g., 8 to 28, 10 to 24, 10 to 20, 10 to 18, 14 to 20, 14 to 18, 8, 10, 12, 14, 16, 18, 20, 22, 24, 28, and/or 30) carbon atoms. In some embodiments, the branched and/or linear alkanes have 6 to 30 (e.g., 8 to 28, 10 to 24, 10 to 20, 10 to 18, 14 to 20, 14 to 18, 10, 12, 14, 16, 18, 20, 22, 24, 28, and/or 30) carbon atoms. In some embodiments, the branched and/or linear alkenes have 6 to 30 (e.g., 8 to 28, 10 to 24, 10 to 20, 10 to 18, 14 to 20, 14 to 18, 8, 10, 12, 14, 16, 18, 20, 22, 24, 28, and/or 30) carbon atoms. In some embodiments, the long-chain alcohols have 6 to 30 (e.g., 8 to 28, 10 to 24, 10 to 20, 10 to 18, 14 to 20, 14 to 18, 8, 10, 12, 14, 16, 18, 20, 22, 24, 28, and/or 30) carbon atoms. In some embodiments, the perfluorocarbons have 4 to 12 (e.g., 6 to 12, 6 to 10, 8 to 10, 4, 6, 8, 10, or 12) carbon atoms.

In some embodiments, the continuous phase of the emulsion includes a solvent that is immiscible with the solvent for the droplets. The continuous phase solvent is not limited, so long as it is immiscible with the solvent for the droplets. The continuous phase solvent can include, for example, water, fatty acids, alcohols (e.g., glycerol, glycerin, ethylene glycol, propylene glycol), deep eutectic solvents, polymers (e.g., polyethylene glycol), ionic liquids, and/or organic solvents (e.g., tetrahydrofuran (THF), dimethyl sulfoxide (DMSO), and/or dimethylformamide (DMF)).

When the emulsion is subjected to ultrasound irradiation, the ultrasound irradiation produces localized cavitation in at least one dispersed droplet of the emulsion. The cavitation can provide a local transient temperature of 500K or more and/or 5000K or less. The dispersed droplet having the localized cavitation can have a local transient pressure of at least 100 bar, at least 1000 bar, at least 5000 bar, or at least 10,000 bar. The cavitation induces nucleation and formation of the particles.

When the emulsion is subjected to ultrasound irradiation, the emulsion bulk temperature maximum and minimum during the irradiation does not increase by more than 50° C. (e.g., by more than 40° C., by more than 30° C., by more than 20° C., by more than 10° C., or by more than 5° C.) for a given emulsion bulk volume of 2 mL or more.

In the emulsion, the one or more particle precursors can each be independently dissolved in the dispersed droplets and/or the continuous phase of the emulsion. When the emulsion is exposed to ultrasound irradiation, the one or more precursors undergo a chemical reaction to form covalent and/or ionic bonds to provide the particles. In other words, the particles are not formed by mere agglomeration or precipitation of the precursors. Rather, a covalent and/or ionic bond is formed between atoms of the precursors to provide the particles.

The one or more precursors can include, for example, organometallic complexes. In some embodiments, the one or more precursors include soluble organochalcogenide precursors (e.g., trialkylphosphine precursors, such as trioctylphosphine (TOP) sulfide, TOP-selenide, and/or TOP-telluride), soluble organophosphorus precursors (e.g., trialkylphosphine, such as trioctylphosphine), soluble organometallic precursors (e.g., transition metal complexes, such as fatty acid complexes and/or acid complexes. Non-limiting examples of precursors include lead oleate, cadmium oleate, indium acetate, zinc acetate, copper oleate, and/or titanium acetate. Particle precursors are described, for example, in Bera D. et al., Materials 2010, 3, 2260-2345, incorporated herein by reference in its entirety.

In some embodiments, the emulsion can include two precursors. The two precursors can be in a molar ratio of 10:1 (e.g., 5:1, 1:1, or 1:5) to 1:10 (e.g., 1:5, 1:1, or 5:1). In certain embodiments, the emulsion can include greater than two precursors. In some embodiments, the emulsion can include one or more precursors at sub-stoichiometric quantities, such that the sub-stoichiometric precursor provides a doping agent that can modulate a property of the generated particles (e.g., optical, electronic, and/or catalytic properties). The dopant can be present in an amount of 0.1 mole % or more (e.g., 1 mole % or more, 5 mole % or more, 10 mole % or more, 20 mole % or more, 30 mole % or more, or 40 mole % or more) and/or 50 mole % or less (e.g., 40 mole % or less, 30 mole % or less, 20 mole % or less, 10 mole % or less, 5 mole % or less, or 1 mole % or less). Non-limiting examples of doping agents can include copper, iron, zinc, lead, manganese, tellurium, and/or indium. Doping agents are described, for example, as described in Santra P. K. and Kamat P. V., J. Am. Chem. Soc. 2012, 134, 5, 2508-2511, incorporated herein by reference in its entirety.

In some embodiments, the emulsion is in the form of a gel. As used herein, a gel refers to a crosslinked system having a liquid and at least one additional component, with soft solid or solid-like properties under static conditions. The gel can retain its shape over a period of time, such that the gel exhibits no flow when in the steady-state, upon visual inspection over a period of at least 10 minutes. By weight, a gel can be mostly liquid, but behaves like solids due to a three-dimensional cross-linked network within the liquid. It is believed that the crosslinking within the fluid provides a gel with its structure (hardness). Examples of additives include, for example, polyacrylic acid, which can provide a crosslinked network in the form of a gel.

In certain embodiments, the emulsion is in the form of a flowing liquid.

In some embodiments, the sonochemical synthesis of the particles of the present disclosure is carried out at a temperature of 150° C. or less (e.g., 100° C. or less, 75° C. or less, or 50° C. or less) and/or the temperature of the sonochemical synthesis is greater than the lowest melting temperature of a given solvent in the emulsion.

During synthesis of the particles, the emulsion can be cycled through a predetermined ultrasound irradiation region. In some embodiments, the emulsion can be continuously cycled through the predetermined ultrasound irradiation region. The predetermined ultrasound irradiation region can be a portion of the emulsion. For example, when the emulsion is a liquid, the emulsion can be (re)circulated in a tank or tube having a predetermined ultrasound irradiation region, such that the entire volume can be insonated in time when circulated through the irradiation region. In some embodiments, when the emulsion is a gel, an ultrasound region can be mechanically scanned over portions of the gel, for example, through physical translation of the sample or translation of the ultrasound source. In some embodiments, a static emulsion sample is exposed to an electronically-controlled multi-element ultrasound array for local gating or electronic steering of the ultrasound field throughout the sample. In some embodiments, a combination of recirculation of the emulsion through an ultrasound irradiation region, mechanical scanning of the ultrasound region over portions of the emulsion (or vice versa), and/or exposure of a static emulsion sample to an ultrasound array or ultrasound field can be used to irradiate a whole or a portion of the emulsion.

The sonochemical synthesis methods of the present disclosure can be applied to large volumes of emulsion and are not limited to a given volume. Thus, the synthesis methods are amenable to scale-up and to large scale (e.g., industrial scale) synthesis, batch synthesis, or for continuous generation (e.g., through emulsion cycling) of particles. For example, the methods can be used on emulsion volumes of 0.5 mL or more (e.g., 10 mL or more, 1 L or more, 5 L or more, 10 L or more, SOL or more, 100 L or more, 500 L or more, to 1000 L or more).

The sonochemical synthesis methods described herein can be controlled spatially and/or temporally. For example, the synthesis can be controlled in time by controlling the application of irradiation and/or raising or decreasing the temperature of the reaction; where the presence of sufficient irradiation allows the particle-formation reaction of the precursors to proceed and the absence of irradiation stops the particle-formation reaction of the precursors, and raising the temperature of the emulsion increases the precursor reaction rate while decreasing the temperature of the emulsion decreases the precursor reaction rate or stops the precursor reaction altogether. As another example, the synthesis can be controlled in space by focusing the ultrasound irradiation on a particular location of the emulsion (e.g., an emulsion in the form of a gel, and/or in the form of a liquid). The progress of the chemical reactions and/or formation of the particles during the sonochemical synthesis can be monitored, for example, by photoluminescence spectroscopy, fluorescence spectroscopy, ultraviolet-visible spectroscopy, infrared, Raman spectroscopy, small angle x-ray scattering (SAXS), and/or time-resolved photoluminescence.

Once the particles are synthesized, isolating the particles from the emulsion can be performed using any suitable method known to a person of skill the art, such as centrifugation, evaporation decantation, flocculation, filtration, or any method thereof.

The particles can be inorganic, organometallic, or organic. As used herein, an “inorganic” particle does not include carbon-hydrogen covalent bonds. An “organometallic” particle includes at least one chemical bond (e.g., covalent, ionic, and/or donor-acceptor bonds) between a carbon atom of an organic molecule and a metal (e.g., alkaline, alkaline earth, metalloids, and/or transition metals) and can include, in some embodiments, transition metal hydrides and metal phosphine complexes. An “organic” particle includes carbon-hydrogen covalent bonds. In some embodiments, the particles include CdSe particles, InP particles, PbS particles, CdTe particles, CdS particles, PbTe particles, PbSe particles, CuS particles, CuSe particles, CuTe particles, ZnS particles, ZnSe particles, ZnTe particles, or any combination thereof. In some embodiments, the particles can include semiconducting particles, conductive particles, and/or insulating particles.

The particles can include magic size particles, where the particles are atomically defined and zero-dimensional magic-size clusters (MSCs). Magic sized clusters (MSCs) include a specific number of atoms that are arranged to form uniform structures with certain sizes. MSCs can have increased stability compared to clusters of other sizes due to their specific structure. In some embodiments, MSCs serve as intermediates for particles (e.g., nanoparticles, microparticles), once nucleation is initiated. The MSCs can be identified, for example, spectroscopically (e.g., using UV-Visible and/or luminescence spectroscopy), by liquid chromatography (e.g., high pressure liquid chromatography), by x-ray diffraction, and/or by nuclear magnetic resonance spectroscopy. In some embodiments, the MSCs have an average diameter of less than 2 nm (e.g., less than 1.5 nm, or less than 1 nm).

In some embodiments, the particles are nanoparticles. The nanoparticles can have an average diameter of 200 nm or less (e.g., 175 nm or less, 150 nm or less, 125 nm or less, 100 nm or less, 75 nm or less, 50 nm or less, 25 nm or less, or 10 nm or less) and/or 2 nm or more (e.g., 5 nm or more, 10 nm or more, 25 nm or more, 50 nm or more, 75 nm or more, 100 nm or more, 125 nm or more, 150 nm or more, or 175 nm or more).

Without wishing to be bound by theory, it is believed that particle formation rate can be influenced by ultrasound power, the volume fraction of the droplet phase compared to the continuous phase, the concentration of the precursor(s), the types of precursors, and/or the reaction temperature. For example, higher ultrasound power can generally cause more cavitation and increase production rate. In some embodiments, higher power alters the particle properties (e.g., size). As an example, increasing the volume fraction of droplets in the emulsion can increase production rates and yields, and/or can affect the particle properties. In some embodiments, higher concentration of precursors affects (e.g., can increase) production rates and yields, and/or affect particle properties (e.g., size and/or shape). In certain embodiments, the type of precursor can influence the yield, the production rates, and/or the final composition of the particles. The reaction temperature can affect the product yield and the rates. For example, for the production of MSCs it can be advantageous to have high ultrasound power, low reaction temperatures, and low precursor concentrations. In some embodiments, for the production of nanoparticles, it can be advantageous to have high acoustic power and high precursor concentrations to increase the amount cavitation and the reaction of the precursors to generate particles.

In some embodiments, the present disclosure describes an emulsion-based CdSe quantum dot preparation method, including preparing a cadmium precursor solution and a selenium precursor solution; mixing the cadmium precursor solution with the selenium precursor solution; adding ethylene glycol and creating an emulsion; cooling the emulsion; continually sonicating the emulsion; and monitoring and maintaining a desired temperature; collecting aliquots; adding ethylene glycol and maintaining constant volume; and separating the generated particles from ethylene glycol. The emulsion can include a high surface tension and low volatility liquid (e.g., an immiscible oil), a cadmium precursor solution, and a selenium precursor.

In some embodiments, the present disclosure provides a CdSe quantum dot preparation method, including preparing a cadmium precursor solution and a selenium precursor solution; mixing the cadmium precursor solution with the selenium precursor solution; cooling mixture of cadmium precursor solution and the selenium precursor solution; continually sonicating the mixture; and monitoring and maintaining a desired temperature; collecting aliquots; and purifying the aliquots using alcohol liquid-liquid extraction.

The following Example describes an embodiment of a sonochemical synthesis of particles of the present disclosure, which can be readily applied to other particles.

### EXAMPLE

### Example 1. Sonochemical Synthesis of CdSe Quantum Dots

The sonochemical synthesis of CdSe quantum dots (QD) in a single liquid bulk phase and in an emulsion system is presented in the present Example. The reactions used cadmium oleate (Cd(OA)₂) and tri-octyl-phosphine selenide (TOP:Se) precursors and it was tracked as a function of sonication time under controlled temperature conditions to isolate the effect of cavitation from that of bulk temperature changes. Conversion from precursors to QD was slow in a single-phase bulk liquid system (i.e., octadecene), but was greatly accelerated in the dispersed system (i.e., octadecene in ethylene glycol emulsion). The emulsion system could increase cavitation efficiency while also delivering the acoustic energy closer to the precursor materials. The capacity of CdSe production using ultrasound in the emulsion system was 3.8 g/L hr. Furthermore, magic-size clusters (MSC) were synthesized in the emulsion system while ultrasmall QDs were obtained from the single-phase bulk solvent system. The differences in synthesis rate and product properties from the emulsion and single-phase system were probed by x-ray diffraction, electron microscopy, photoluminescence and small angle x-ray scattering (SAXS). Finally, precise temporal control of QD synthesis was demonstrated by on-off cycling of the ultrasound waves.

### Chemicals

1-octadecene 90%, oleic acid 90%, oleylamine 70%, cadmium oxide≥99.99%, selenium≥99.99%, trioctylphosphine (TOP), dodecane, and hexanes were purchased from Millipore-Sigma (St Louis, Mo. USA). Ethylene glycol was purchased from Fisher Scientific (Hampton, N.H. USA). All chemicals were used as received.

### Precursor Preparation

The cadmium precursor, 84 mM cadmium oleate, was prepared in the following way. To a round bottom flask, 0.256 g of cadmium oxide, 20 mL octadecene, and 2.6 mL of oleic acid were added. Using a Schlenk line setup, the flask is degassed by applying vacuum while stirring at 800 RPM using a magnetic stir bar. Under nitrogen, the flask was heated to 270° C. and it was held at this temperature for 30 minutes or until the mixture becomes clear; the temperature was then held for 30 additional minutes. At this time, the temperature was lowered to 150° C., and 1.3 mL of oleylamine was added. The temperature was then lowered to 100° C., and the flask was degassed for 30 minutes. Finally, the temperature was lowered to room temperature. The selenium precursor, 1 M TOP:Se, was prepared by mixing Se powder and TOP overnight in a glove box until all the Se was dissolved and the solution was clear and colorless.

### Sonochemical Quantum Dot Synthesis

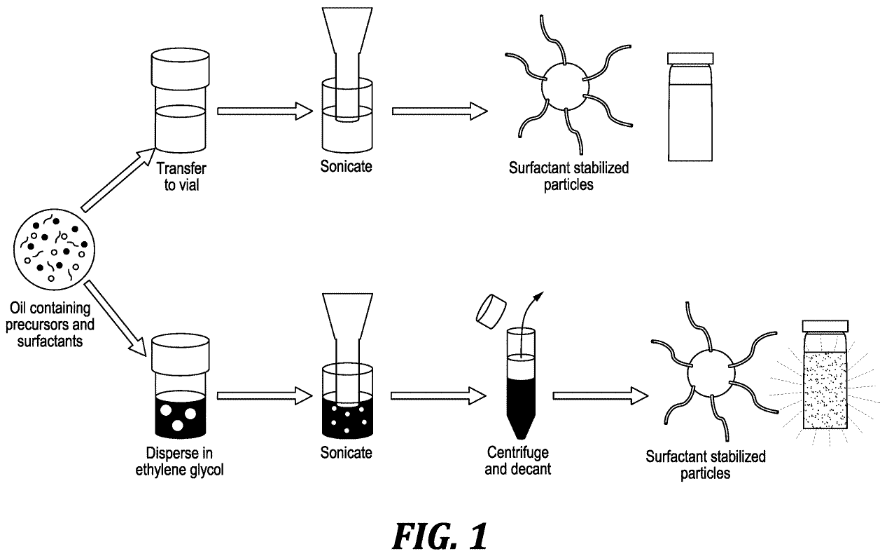

The cadmium precursor was first mixed with the selenium precursor at a 1:4 molar ratio. A schematic of the synthesis process was depicted in FIG. 1. In the emulsion system, 2.245 mL of the cadmium precursor was mixed with 0.755 mL of the selenium precursor in a 20 mL glass scintillation vial. The vial was hand-shaken to mix the two precursor solutions, before adding 7 mL of ethylene glycol. The capped vial was again shaken by hand vigorously to create a coarse emulsion. The vial was then placed in a cooling bath containing water at 20° C. Sonication was then initiated using Branson 450 Digital Sonifier, equipped with a ⅜″ titanium horn directly immersed 0.5 cm into the solution. Sonication was performed continuously at a 20% power setting on the control panel, which had been calibrated to be equivalent to a power dissipation of 12.6 W. Sonication was then temporarily stopped to collect sample aliquots at each relevant time stamp, and an equivalent volume of ethylene glycol was added into the scintillation vial such the volume was always kept at 10 mL. The volume of aliquot that was withdrawn was such that there was approximately 250 μL of oil phase (octadecene) in each aliquot. The water in the cooling bath was also exchanged with fresh cold water, and the sonication was continued. The temperature of the vials was also monitored with a thermocouple in order to separate the effect of sonication/cavitation from that of a possible bulk temperature increase.

Each sample aliquot was then centrifuged and decanted to separate the dispersed oil phase containing the quantum dots from the continuous ethylene glycol phase in the emulsions. These samples were referred as ‘unpurified’ because of the presence of excess unreacted precursors and organic components. The ‘as-synthesized’ samples were characterized by small angle x-ray scattering (SAXS) and diluted about 100-fold in octadecene for UV-Vis spectroscopy as a function of sonication time. For x-ray diffraction (XRD), the as-synthesized samples were purified by simply precipitating with the addition of excess ethanol. The powder was then separated and deposited onto a silicon wafer for analysis. Alternatively, the as-synthesized samples were diluted 10-fold in dodecane, and purification was performed by liquid-liquid extraction using an equivalent volume of methanol (250 μL) that was changed three times. After each addition of methanol, the samples were vortexed and centrifuged. Care was taken to make up the dodecane lost during the extraction process to prevent the particles from precipitating, since precipitates were not redispersible. After cleaning, particles were also characterized by SAXS, diluted into hexanes 10-fold for UV-Vis spectroscopy, 1000-fold for photoluminescence (PL) spectroscopy, and 100-fold for transmission electron microscopy (TEM).

In the single-phase system, the sonication procedure was very similar. The only difference was that the 10 mL reaction volume was entirely composed of the precursor mixture. No ethylene glycol was used and no emulsification occurred. Also, for these samples, no makeup solvent was added upon removal of sample aliquots as a function of time. The as-synthesized samples were characterized with SAXS and diluted about 10-fold in octadecene for UV-Vis spectroscopy. Purification of these samples was also performed by liquid-liquid extraction using an ethanol wash of equivalent volume (250 μ L) three times, after which, the particles spontaneously adhered to the walls of the plastic centrifuge tubes. For XRD sample preparation, the purified samples were redispersed into toluene and drop-cast onto a silicon wafer. Samples were also redispersed into 250 μL dodecane for characterization in dispersion with SAXS, and then diluted into hexanes 10-fold for UV-Vis spectroscopy, 1000-fold PL spectroscopy, and 100-fold for TEM.

### UV-Visible (UV-Vis) and Photoluminescence (PL) Spectroscopy

Both UV-Vis and PL spectroscopy were performed using quartz cuvettes with a 1 cm pathlength. UV-Vis spectroscopy was performed using a Thermo Scientific Evolution 300 (Waltham, MA) spectrophotometer operating over a 300-700 nm wavelength range. PL was performed using a Molecular Devices SpectraMax M5 (San Jose, Calif.) fluorescence spectrophotometer.

### Transmission Electron Microscopy (TEM)

TEM was performed using FEI Tecnai G2 F20 Super-Twin (Hillsboro, OR) operating at 200 kV. Samples were deposited over a copper TEM grid with 300 mesh carbon by drop casting 3 μL of sample and letting this dry.

### Small Angle X-Ray Scattering (SAXS) and X-Ray Diffraction (XRD)

SAXS was performed using Anton-Parr SAXSess (Graz, Austria) Kratky camera in a line-collimation (0.26 A smearing) configuration with Cu K-a radiation. Samples are mounted using quartz capillaries of 1 mm in diameter. X-ray scattering was collected using a Fujifilm phosphor image plate (Japan) that is then developed in a PerkinElmer Cyclone Plus plate reader (Shelton, USA). The 2D raw data was converted to a 1D profile and subsequently corrected by subtraction of the scattering from the solvent and from the empty capillary. Absolute scaling of SAXS intensity was performed using water standard. XRD was performed using Bruker D8 (Billerica, Mass.) using a beam that was collimated to a 1 mm cross-section with Cu K-α radiation. X-ray diffraction spectra was collected using Pilatus 100 K detector. The 2D raw data was then converted to a 1D profile and subsequently corrected by subtracting the broad background signal.

### Temperature Profile of the Mixture with Sonication

The temperature inside the reaction vessel was measured by using a thermocouple embedded directly inside the mixture. The temperature of the emulsion system was higher than that of the single-phase system because there are more cavitation events in the emulsion system. The liquid-liquid interface between ethylene glycol and octadecene acted as heterogeneous nucleation site for bubbles. The temperature of the emulsion system started to go down after 90 minutes of sonication. This was likely due to the decrease of the oil phase as aliquots were taken out, resulting in overall less liquid-liquid interface and therefore less total number of cavitation events as well.

### Control Sample Using a Hot Plate

To ensure that particle formation was due to ultrasound and not temperature, a mixture with an identical recipe was heated on a hot plate while stirred for 3 hours. No change was observed in the spectra, indicating that no QDs were formed.

### Pre-Cleaned UV-Vis Spectra of Samples from Emulsion System

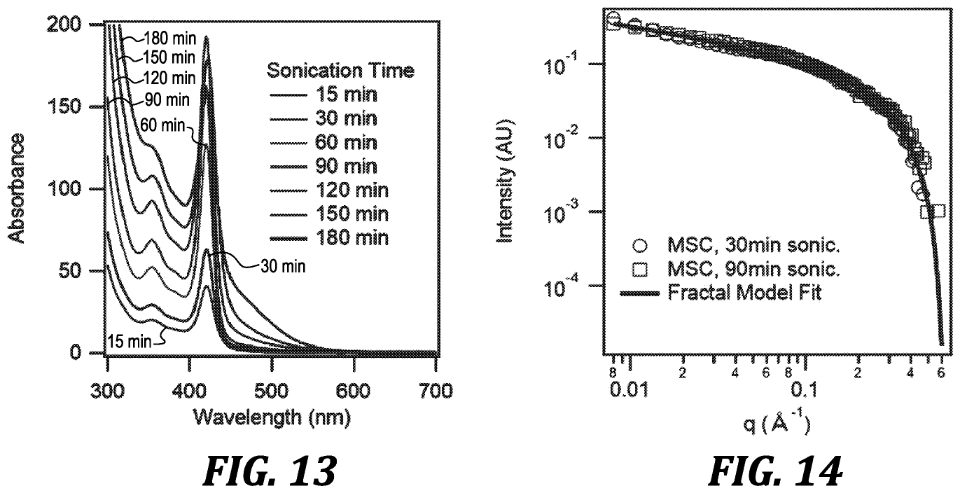

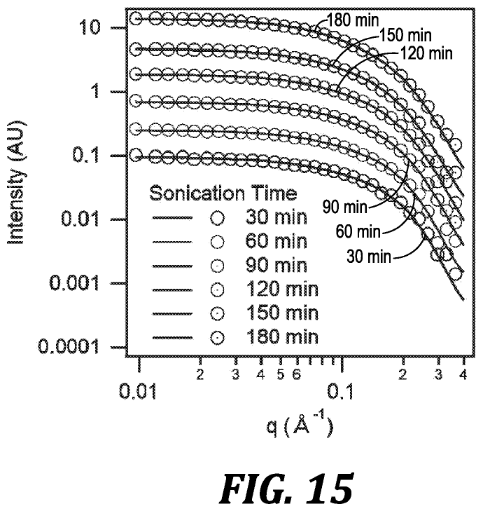

The UV-Vis spectra of samples from the emulsion system before cleaning was shown in FIG. 13. These spectra were almost identical to those after cleaning. One notable difference was that the sharp peak of the pre-cleaned samples was centered at 420, while that of the cleaned samples was at 425 nm. This difference was likely due to a difference in ligand population on the surface of the QDs.

### MSC SAXS Data Model Fit

Fitting of MSC SAXS data was performed using SasView, a software to analyze small angle scattering data. The data was fit to the fractal model, which calculates the scattering intensity from aggregates of spheres:

l(q)=ΦV(ρₚ−ρₛ)²P(q)S(q)+background

where ρ is the volume fraction of particles, V is the volume of a single particle, ρₚ is the scattering length density of the particle, ρₛ is the scattering length density of the solvent. P(q) and S(q) are the form factor of a sphere and structure factor, respectively, and are defined as

$$P ( q ) = {[ \frac{3 ( sin ( qR ) - q R sin ( qR )}{{( qR )}^{3}} ]}^{2}$$

$$S ( q ) = 1 + \frac{{D}_{f} Γ ( {D}_{f} - 1 )}{{[ 1 + \frac{1}{{( q ξ )}^{2}} ]}^{( {D}_{f} - 1 ) / 2}} \frac{sin [ ( {D}_{f} - 1 ) {tan}^{- 1} ( q ξ ) ]}{{( qR )}^{{D}_{f}}}$$

where R is the particle radius, D_{f} is the fractal dimension, Γ is the gamma function, and ξ is the correlation length representing cluster size. When fitting, the volume fraction, particle radius, and fractal dimension were allowed to vary to fit the data. All other parameters were fixed. There was some product loss during the QD purification process and therefore the intensity could be scaled to determine particle concentration. Hence, the fitted value of the volume fraction parameter is meant to arbitrarily scale model intensity to data intensity. Similarly, the values of scattering length densities are arbitrarily set since they serve to scale the SAXS curve up and down in a log-log plot. The background is set to 0 because the solvent was subtracted. The correlation length is set to an arbitrarily large value of 10,000 Å since the continued rise in intensity at low-q means that the sizes of the aggregates are beyond the resolution of the SAXS instrument. FIG. 14 shows the model fit to the SAXS data from the emulsion system after 30 minutes of sonication. The relevant parameters obtained are the particle radius and fractal dimension, which are 7.3 Å and 1.3, respectively.

### SAXS Fit of QDs Synthesized in the Single-Phase Bulk System

SAXS data was fitted to an ensemble of spherical particles using the Irena, a tool suite within Igor Pro software.

### CdSe Conversion Calculation

The linear absorption coefficient, α[=]cm⁻¹, and the QD molar extinction coefficient, ϵ[=]M⁻¹cm⁻¹ are both a function of energy and can be related through

$$ε ( E ) = \frac{{N}_{A} V \times α ( E )}{1000 \times ln ( 10 )}$$

Where N_{A} is Avogadro's number and V is volume of a CdSe QD. For CdSe QDs in the size range of 2-8 nm, the oscillator strength across the spectra is redistributed across existing optical transitions. In other words,

∫αdE=constant

for any ensemble of CdSe QDs. This is especially convenient if the sample contains multiple populations of QDs with multiple overlapping peaks, such as the ones from the emulsion system at longer sonication times, and the size dependent extinction coefficient cannot be directly used.

First, it was assumed that for samples from the emulsion system, the sample up to sonication time of 90 minutes is exclusively composed of MSCs, and therefore the concentration of QDs could be obtained using Beer's law:

A=ϵlC

where A is the absorbance, ϵ is the molar QD extinction coefficient, l is the path length, and C is the concentration. The value of ϵ is 1.60×10⁵ M⁻¹ cm⁻¹. The concentration of (CdSe) cation-anion pair is obtained by multiplying the QD concentration by 33.5, since the absorption peak at 420 nm corresponds to MSCs (CdSe)₃₃ and (CdSe)₃₄. The area under the UV-Vis spectra, ∫ A dE, is calculated by using the trapezoidal rule from the UV-Vis data. The area per (CdSe) cation-anion pair is then calculated by dividing the area by the (CdSe) concentration calculated directly from E earlier.

$$\frac{Area}{( CdSe )} = B = \frac{\int AdE}{[ ( CdSe ) ]}$$

The value of B is averaged from sample from the emulsion system up to 90 minutes of sonication, since it was assumed that the sample only composed of MSCs up to this point. This value is then used with the area, ∫A dE, to calculate the (CdSe) cation-anion pair concentration for all samples. A summary of this calculation is shown in Table 1.

TABLE 1
Summary of the calculations used to determine the concentration of (CdSe)

| Sonication | Absorbance | QD conc. | ¹(CdSe) | | | ²(CdSe) | ³(CdSe) |
|---|---|---|---|---|---|---|---|
| Time | at 420 nm | (M) | conc. (M) | Area | B (M⁻¹) | conc. (M) | conc. (M) |
| 15 | 4.10E+01 | 2.56E−04 | 8.59E−03 | 1.93E+01 | 2.25E+03 | 9.24E−03 | 7.65E−03 |
| 30 | 6.32E+01 | 3.96E−04 | 1.33E−02 | 2.87E+01 | 2.17E+03 | 1.37E−02 | 1.18E−02 |
| 60 | 1.28E+02 | 7.99E−04 | 2.68E−02 | 5.19E+01 | 1.94E+03 | 2.48E−02 | 2.38E−02 |
| 90 | 1.63E+02 | 1.02E−03 | 3.41E−02 | 6.85E+01 | 2.01E+03 | 3.28E−02 | 3.04E−02 |
| 120 | 1.93E+02 | | | 9.41E+01 | | 4.50E−02 | |
| 150 | 1.76E+02 | | | 1.13E+02 | | 5.39E−02 | |
| 180 | 1.58E+02 | | | 1.32E+02 | | 6.30E−02 | |

1. Calculated by multiplying the QD concentration by 33.5
2. Calculated by dividing ∫ A dE by the average B.
3. Calculated from the QD concentration, particle radius of 0.73 nm from SAXS data fitting, and assuming a CdSe density of 5.82 g/mol.

The calculated concentration of (CdSe) from method 2 agrees well with the values from method 3, which validates the assumption that those samples are composed of only MSCs (CdSe)₃₃ and (CdSe)₃₄. Values from method 1 also agrees with values from method 3, which validates the radius parameter from SAXS data fitting.

### Results

To investigate the total acoustic power that was delivered to the system, calorimetry was performed as devised by Kikuchi and Uchida using water in an insulated environment at the same sonication horn parameters that are used for QD synthesis. See, e.g., Kikuchi, T.; Uchida, T. calorimetric Method for Measuring High Ultrasonic Power Using Water as a Heating Material. J. Phys. Conf. Ser. 2011, 279 (1), 6-11, incorporated herein by reference in its entirety. The power delivered by the ultrasound horn was set to 12.6 W for all synthesis. At this power, the reaction temperature stabilized at a steady state of 55° C. in the single-phase system and 65° C. in the emulsion system. Both of these two temperatures were significantly lower than the typical temperatures used in either the hot-injection or heat-up synthesis methods. Examples of temperature profiles as a function of time were provided for each reaction. To ensure that QD formation was due to ultrasound and not due to the mild rise in temperature, a control was performed where the mixture was heated to 60° C. on a hot plate. UV-Vis did not indicate the formation of any particles even after 3 hours of heating (FIG. 12).

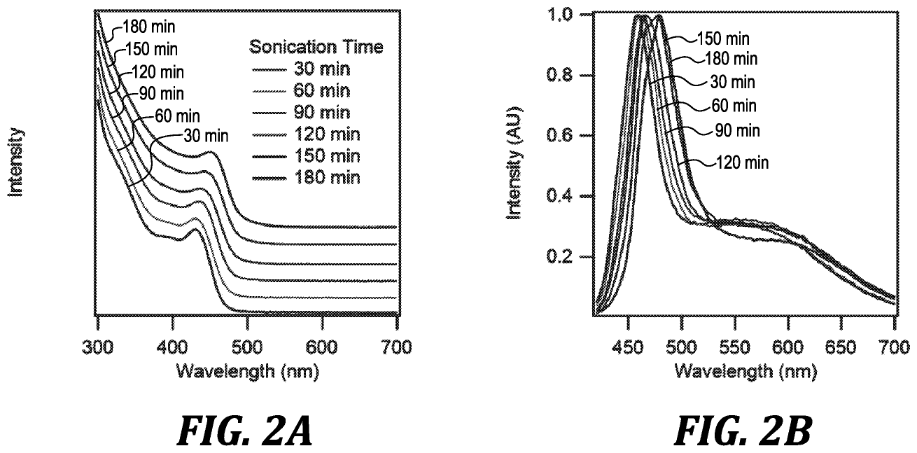

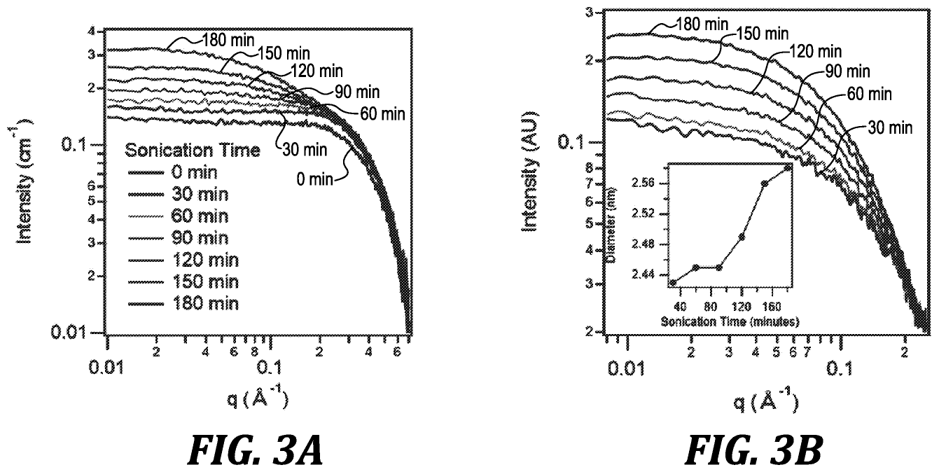

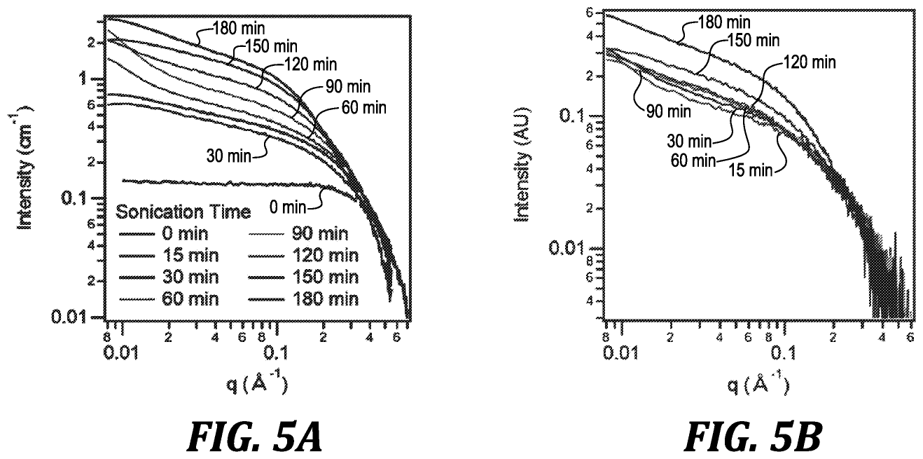

Both the single-phase and emulsion systems were sonicated and tracked for a total of 3 hours. An aliquot of the sample was taken at several time stamps to monitor the QD growth with sonication time. FIGS. 2A and 2B; and 4A and 4B show the UV-Vis and photoluminescence (PL) spectra of the single-phase and emulsion systems, respectively. UV-Vis spectra are also taken before and after QD purification. Although absorbance and PL spectra carry rich information regarding the QDs, they are inherently optical in nature and can be influenced by various factors, including the geometry of the particles, the flocculation of particles, and the presence of ligands on the surface of the QDs. To more directly probe the QD structure, small angle x-ray scattering (SAXS) was also performed (FIGS. 3A, 3B, 5A, and 5B). SAXS was also performed before and after sample purification to gain a complete picture of the changing structures during synthesis and purification processes. After sonication was complete, the samples were also characterized by x-ray diffraction (XRD) and transmission electron microscopy (TEM).

As the precursor mixtures were sonicated in the bulk single-phase and in the emulsion systems, particles formed and steadily grew with longer sonication time. In the single-phase or ‘bulk’ system, the first excitonic peak in the absorbance spectra red-shifted with longer sonication time (FIG. 12). See, e.g., Murcia, M. J.; Shaw, D. L.; Woodruff, H.; Naumann, C. A.; Young, B. A.; Long, E. C. Facile Sonochemical Synthesis of Highly Luminescent ZnS-Shelled CdSe Quantum Dots. Chem. Mater. 2006, 18 (9), 2219-2225. Similarly, the band edge emission in the PL spectra shifted with longer sonication time (FIG. 2B). The red-shift indicated decreasing bandgap of the particles, suggesting increasing an increase in particle size. Using the empirical formula that relates the wavelength of the first excitonic absorbance peak to the particle size of CdSe QDs (see, e.g., Jasieniak, J. et al., Re-Examination of the Size-Dependent Absorption Properties of CdSe Quantum Dots. J. Phys. Chem. C 2009, 113 (45), 19468-19474, incorporated herein by reference in its entirety), particles were estimated to grow from a diameter of 1.74 nm after 30 minutes of sonication to 1.91 nm after 180 minutes of sonication. All the PL spectra exhibited a broad emission at high wavelengths in addition to the dominant band edge emission. These longer wavelength emissions were due to the presence of deep traps and have been previously observed for ultrasmall CdSe QDs.

SAXS characterization of structure in dispersion further confirmed the growth of ultra-small QDs with increasing time (FIG. 3). In SAXS, the scattering intensity profile was related to the square of the Fourier transform of the spatial correlation function of electrons in the sample. The intensity was typically plotted against the scattering wave vector q, which was dependent on the scattering angle and the X-ray energy or wavelength. Longer spatial correlations appeared as features at lower q values, while shorter correlations appeared as features at high q. FIG. 3A shows the scattering profiles for the single-phase bulk samples as-synthesized and before cleaning. The data was presented after normalization to an absolute intensity, which allowed for direct correlation of SAXS intensity to the concentration of QDs in dispersion.

Notably, at time 0 there was already a scattering profile that arose due to the formation of inverse micelles in the precursor solutions. At longer sonication times, scattering contributions from CdSe QDs started to dominate the signal. This was especially evident at low-q, where a second low-q Guinier ‘hump’ was observed in addition to that found for the precursors prior to sonication. After cleaning the samples, the scattering from the inverse micelles in the precursor was no longer observed, and only a single Guinier turnover was observed at low-q (FIG. 3B). The scattering profiles of purified and ‘cleaned’ samples were no longer placed in an absolute scale because there was an inevitable loss of product that was associated to the cleaning process, and the intensity of each profile could no longer be directly compared to each other. Nevertheless, the shape of the scattering profiles only depended on the geometry of the QDs and, under sufficiently dilute conditions, should be independent of the QD concentration. In FIG. 3B, the scattering intensity was arbitrarily scaled such that the intensity was matched at high-q for qualitative comparison of their shape. As sonication proceeded, the Guinier region shifted towards lower q values, indicating the formation of larger particles. Using the Irena software tool suite, the scattering profiles were fit to a model to extract the size of the QDs. Scattering fits were also provided in the supplemental information. The mean diameter of the particles grew from 2.43 nm after 30 minutes of sonication to 2.58 nm after 180 minutes of sonication (FIG. 3B inset). The size observed from SAXS was larger when compared to the size obtained from UV-Vis spectroscopy because the head groups of stabilizing ligands that were adsorbed to the surface of the QDs could also contribute to the SAXS signal due to their electron density.

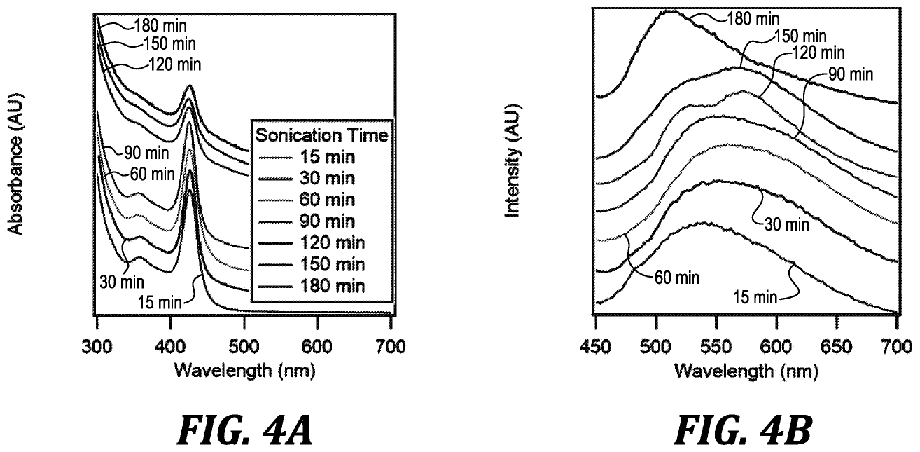

When sonochemical QD syntheses were performed in emulsion systems, the results were drastically different. While sonication of the single-phase or ‘bulk’ system produced ultrasmall QDs, sonication of the emulsion system produced magic-sized QDs, also commonly known as magic-sized crystals (MSC) or clusters. As the sample was sonicated, a gradual red-shift of the first excitonic peak was not observed in the UV-Vis spectra. Instead, a rather sharp absorbance peak at 425 nm (fwhm≈18 nm) was observed that did not shift with increasing sonication time but did increase in intensity (FIG. 4A). The PL spectra of these samples also exhibited a broad, ‘white-light’ emission but with no characteristic band-edge emission peak. Such a sharp absorbance peak coupled with a broad emission with no band-edge was characteristic of MSCs. In particular, the absorption peak at this wavelength corresponded well to MSCs (CdSe)₃₃ and (CdSe)34. Interestingly, the relative height of the peak at 425 nm started to decrease after 90 minutes of sonication, and an absorption tail started to appear. This turning point at 120 minutes was also observed in the PL spectra (FIG. 4B). Up until 90 minutes of sonication, the emission was almost entirely characteristic of surface trap emissions. However, at ≠120 minutes of sonication, a peak started to develop that blue-shifted with longer sonication time, bearing resemblance of a band-gap emission peak. The formation of a tail in the UV-Vis spectra and a peak in the PL spectra suggested the formation of larger QDs is taking place after extensive sonication.

SAXS was also performed on both pre-cleaned samples and purified samples from the emulsion system (FIGS. 5A and 5B). Similar to the single-phase system, SAXS was performed and transformed to an absolute scale for the as-prepared samples for the emulsion system (FIG. 5A). The scattering intensity increased steadily with longer sonication time, which meant that the volume fraction of particles increased with sonication time. The Guinier hump near 0.2 A⁻¹ was related to the primary particles, viz. CdSe QDs, and the continued rise in intensity towards low-q suggested that these particles were associating to create large-scale structures. The intensity continued to rise even at the lowest-q values, which meant that the size of these aggregates was beyond the resolution of the SAXS instrument. These samples were subsequently diluted 10-fold, purified, and SAXS was performed again on the ‘cleaned’ samples in the absence of excess precursor materials (FIG. 5B). Similar to FIG. 3A, these SAXS profiles were not placed in an absolute scale since there were some losses of material in the purification process. Instead, the scattering profiles were normalized to have matching intensities at high values of q. Even after purification and a 10-fold dilution, the large flocs continued to persist. This was evidenced by the continued rise in intensity at low-q.

Interestingly, the profiles overlapped until after 120 minutes, which matched well with the turning point of the UV-Vis spectra when the intensity of the sharp peak began to decrease (FIG. 4A). This meant that the rise in volume fraction with sonication time of the pre-cleaned samples (FIG. 5A) up to 120 minutes was not due to the growth of QDs, but rather to an increase in the total quantity of MSCs. To further extract structural information, the scattering profiles of the cleaned samples up to 90 minutes of sonication were fitted to a model of fractal aggregates of spherical primary particles. From this model, a primary particle radius of 7.3 A was obtained that was consistent with the size found by Kasuya for MSCs. See, e.g., Kasuya, A. et al., Ultra-Stable Nanoparticles of CdSe Revealed from Mass Spectrometry. Nat. Mater. 2004, 3 (2), 99-102. The primary particles then formed aggregates with a fractal dimension of 1.3, which corresponded to low-density aggregates. Details of the SAXS models and fits were provided below. After 120 minutes, the SAXS profile supported the conclusion that larger QDs were formed, which was most evident in the SAXS profile at 180 minutes (FIG. 5B). The feature at 0.2 A⁻¹ that corresponded to the MSCs was still there, but another feature at 0.1 A⁻¹ emerged that corresponded to larger QDs.

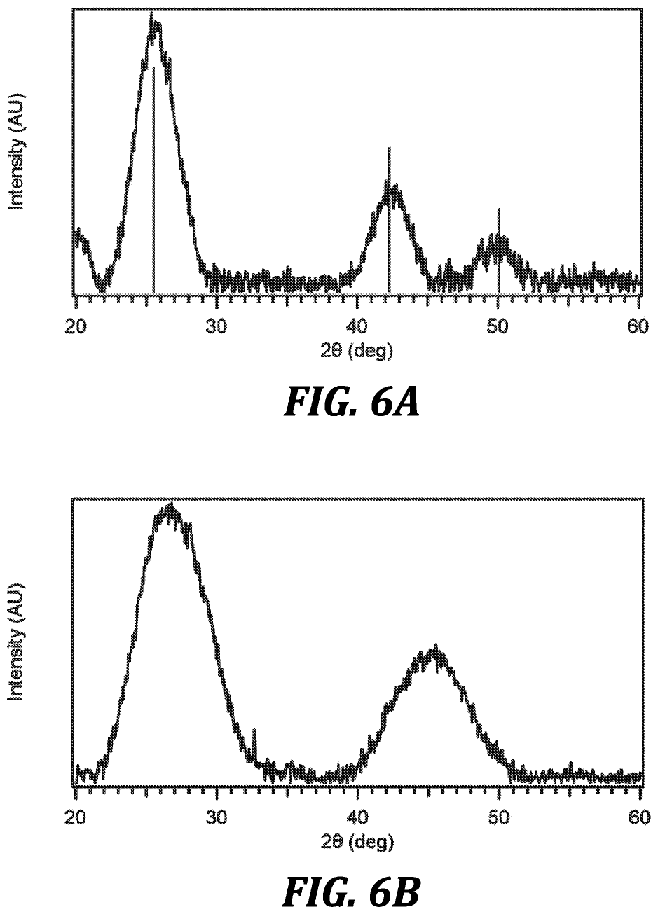

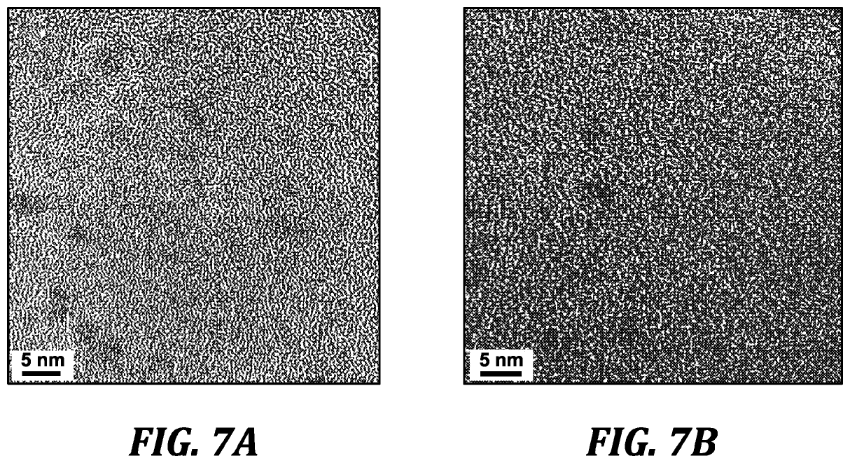

At the end of 3-hours of sonication, samples from both the single-phase and emulsion system were also purified and characterized by XRD (FIGS. 6A and 6B) and TEM (FIG. 7). XRD showed significant peak broadening due to the small sizes of the QDs in both the single-phase and in the emulsion synthesis systems. The XRD profile for the sample from the single-phase system matched that of cubic zincblende CdSe (PDF 04-003-6493, FIG. 6A). However, care was taken because such significant peak broadening could not decisively differentiate between cubic zincblende and hexagonal wurtzite structures. The excess signal at low angles was likely due to remaining ligands in the sample. The peaks of the sample from the emulsion system were even broader (FIG. 6B) because of the even smaller QD sizes. It was likely that a sum of overlapping peaks resulted in the large peak that was observed at 45°. As such, the profile could not be matched to one from a database. Still, this form of XRD profile was consistent with previous characterizations of CdSe MSCs and likely formed a structure similar also to CdS MSCs.

FIGS. 7A and 7B show TEM images of QDs prepared through both synthesis processes. The contrast in TEM was also limited because of the very small size of the QDs. Furthermore, lattice fringes were not observed because ultrasmall particles and MSCs had nearly 80% of the atoms on the surface, which left only two unit cells in the core of the particles. The observed QDs from the end time-point of the emulsion synthesis systems was found to be larger than the expected sizes of MSCs, which was expected from the formation of larger QDs after successive sonication. These particles were also larger than the size that was obtained from SAXS profiles after 30 minutes of sonication, which supported the idea that MSCs were converted into regular-sized QDs after prolonged sonication in emulsions. No MSCs could be observed in TEM. Given the very low contrast that is observed for ultrasmall QDs, the contrast of MSCs was even lower and difficult to image with TEM.

It was important to make a distinction between MSCs and ultrasmall QDs. Ultrasmall QDs were simply small-sized QDs. On the other hand, MSCs were at the interface between a molecule and particle. They had a precise number of atoms in the single crystal and thus resulted in a precise bandgap, leading to a sharp absorbance peak.

Furthermore, the allowed number of atoms in the single crystal was also precisely defined. MSCs did not grow incrementally, but rather they transitioned from one allowed configuration to another. The result was that absorbance peaks did not incrementally move or shift, but rather they ‘jumped’ from one discrete wavelength to another. The MSCs that were observed was (CdSe)₃₃ and (CdSe)₃₄. However, other families of MSCs in CdSe could be readily adapted to the present synthesis methods. This was in contrast to regular QDs where the absorbance peaks incrementally shifted as particles incrementally grew (FIG. 2A).

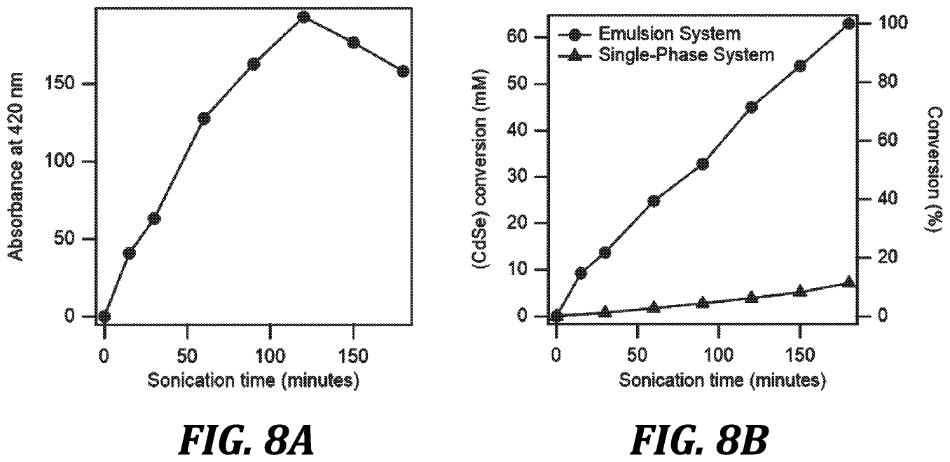

Interestingly, in UV-Vis spectra of samples obtained from the emulsion systems (FIG. 4A), the shrinking of absorption peaks at 425 nm was not just relative, but absolute. Before the purification process, the absorbance peak was at 420 nm (FIG. 13). The absorbance at 420 was quantitatively tracked with sonication time (FIG. 8A). Even after about 120 minutes of sonication, the absorbance at 420 nm continued to rise with sonication but without any shift in wavelength. This suggested that there was an increasing number of MSCs in the system as the sample was sonicated. Afterwards, however, the absorbance at 420 nm decreased and a tail at higher wavelengths emerged. This coincided with the appearance of a second Guinier region in the SAXS profile after 150 minutes of sonication (FIG. 5B). This suggested that the regular QDs were synthesized at the expense of the MSCs. In other words, the regular QDs were not side products of the entire sonication process. Instead, QDs were formed from reactions of

MSCs after these were formed. If only MSCs were desired, then the sonication process could be stopped at an appropriate time.

Aside from the difference in product properties, the rate of conversion from precursor to QDs was remarkably faster in the emulsion systems. This was evident from the SAXS profiles in absolute scale of the pre-cleaned samples. Comparing the samples from the single-phase systems (FIG. 3A) to the emulsion systems (FIG. 5A), the scattering intensity was much higher in the emulsion systems. But perhaps the most obvious sign of this is when performing dilutions for UV-Vis spectroscopy. To get sufficient light penetration through the as-synthesized samples, the single-phase system samples needed to be diluted 10-fold. In contrast, samples from the emulsion systems needed to be diluted more than 100-fold or they would saturate the detectors. To further quantify the rate of QD or MSC synthesis, the absorption spectra is converted to an energy scale, and then integrated from 1.77 eV to 3.82 eV (325 nm-700 nm). Since the integral of the absorption coefficient over the photon energy (i.e., ∫αdE) had a negligible size dependence, the integral of absorbance over energy (i.e., ∫A dE) could be used to quantify the conversion of Cd and Se precursors into CdSe across different ensembles of QDs (FIG. 8B). Details and cross-validation of this calculation were given in the supplemental information. After 3 hours of sonication, complete conversion was observed in the emulsion system, while only 11% conversion sis observed in the single-phase bulk system. Using a linear fit, the rate of conversion in the emulsion system and in the single-phase system was 3.8 g/L hr and 0.48 g/L hr, respectively, where the conversion rate of the former was comparable to that of a typical hot-injection synthesis of CdSe QDs. For example, an optimized hot-injection synthesis CdSe QDs yielded about 3.7 g/L, and it took approximately one hour including the initial heating-up of the reaction mixture. Thus, sonication in the emulsion system provided a competitive conversion rate for the synthesis of CdSe. Moreover, this rate could likely be further increased by delivering more ultrasound power, using larger volume fractions of oil, increasing precursor concentrations, using a heterogenous selenium source, and/or increasing the reaction temperatures.

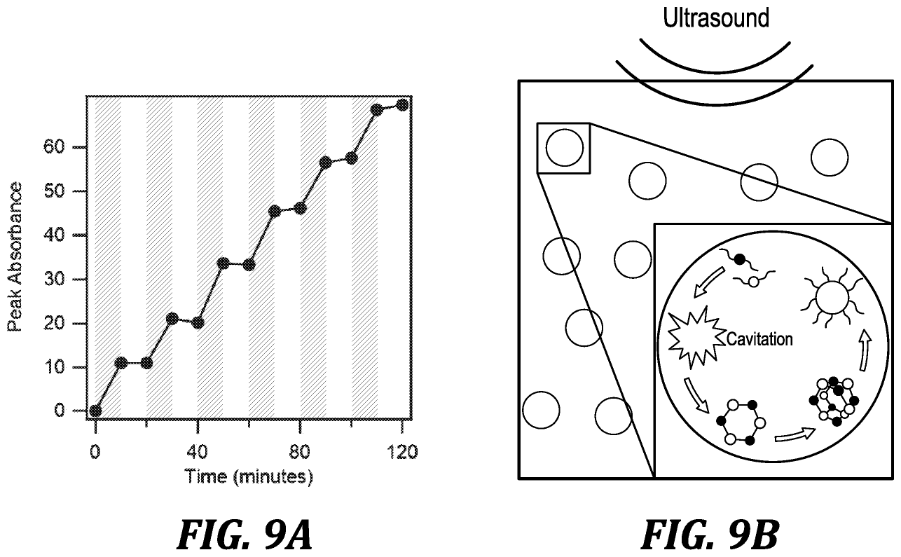

In addition to this, when using sonochemical synthesis methods, the temporal control over when the synthesis starts and stops was remarkable. An experiment where sonication was systematically turned ‘on’ and ‘off’ every 10 minutes was also performed with the emulsion system. The absorbance at 420 nm was also tracked with elapsed time (FIG. 9A). The data clearly showed that the absorbance increased only when the sonication was turned ‘on’, which resulted in a step-like growth curve. There were several important outcomes from this experiment that suggested that precise temporal control of the reaction could further elevate QD synthesis methods. This conclusively demonstrated that conversion of precursors to QDs was a direct result of ultrasound and not due to a rise in the temperature of the sample, which was a side effect of power dissipation during sonication. Although letting the temperature rise to higher values may speed up the production of QDs, such a precise level of temporal control may not be possible and it may also interfere with the formation of MSCs instead of larger QD particles in emulsion systems. Second, the choice to use TOP as opposed to secondary phosphines such as diphenylphosphine was necessary to carefully control the sonochemical reactions. There were several separate mechanisms for the formation of CdSe monomers. One mechanism required the decomposition of a tertiary phosphine-chalcogenide to form highly reactive H₂Se. Another mechanism did not involve precursor decomposition and instead was a direct reaction of secondary phosphine-chalcogenides and metal carboxylates. Secondary phosphines were more reactive than tertiary phosphines, and CdSe MSCs could be synthesized at temperatures as low as 45° C. using diphenylphosphine selenide. However, in this Example, the low reactivity of TOP:Se decreased the likelihood of unwanted reactions progressing at low bulk temperatures. Yet, the extreme conditions that were locally exhibited by cavitation were more than sufficient to decompose TOP:Se and to drive the conversion of CdSe QDs and MSCs. These design choices open up the door towards efficient, on-demand, synthesis of QDs, where the reaction could be started and stopped simply by turning the ultrasound on and off. Moreover, high-intensity focused ultrasound (HIFU) could also be used to spatially control the synthesis of QDs and MSCs in specific locations.

Two questions remain to be answered: 1) compared to the single-phase bulk system, why is precursor conversion much faster in the emulsion system and 2) why are the resulting products different? The answers to these questions were related. The synthesis of QDs was driven by the extreme conditions locally induced by cavitation. In the single-phase system, bubbles must nucleate homogenously and this was terribly inefficient. In such cases, cavitation tends to occur predominantly at interfaces such as the vial walls and the surface of the sonication horn. In the emulsion systems, the liquid-liquid interface of the droplets acts as heterogenous nucleation sites for bubbles, which was much more favorable than homogenous nucleation. These ‘weak spots’ in the system have been reasoned previously, although no control experiment in a single-phase bulk system was performed. Moreover, the cavitation bubbles were generated exactly where they were needed. This meant that the sonication energy was dissipated locally where the precursor materials were also located (i.e., in the droplets). Hence sonication of the emulsion system resulted in more frequent and numerous cavitation events that were more efficiently distributed near the precursors and that quickly drove the nucleation and growth of QDs (FIG. 9B). Coincidentally, the liquid-liquid interface may also serve as a nucleation site for QDs, and it was well known that the energy barrier for heterogenous nucleation was lower than that of homogenous nucleation of QDs.

The high concentration of precursors and fast conversion of precursors to QDs was key to the synthesis of MSCs in the emulsion systems. Without wishing to be bound by theory, it was believed that a mixture with high precursor concentrations offered a well-defined pathway towards synthesizing MSCs, and that the MSCs were stable and resistant towards growth and dissolution. This was because the MSCs and their ligands form inorganic-organic fibers that, in turn, create ordered mesophases that stabilize the clusters against aggregation. It was believed that the stability of the MSCs was specifically due to the formation of fibers, rather the assembled mesophases. The lack of sharp peaks in the SAXS profiles (FIG. 5) suggested that highly-ordered mesophases were not created. However, the low fractal dimension of the aggregates (D_{f}=1.3) did suggest that the MSC aggregates form a nearly linear structure resembling a fiber, and this seemed to be sufficient to keep the MSCs stable.

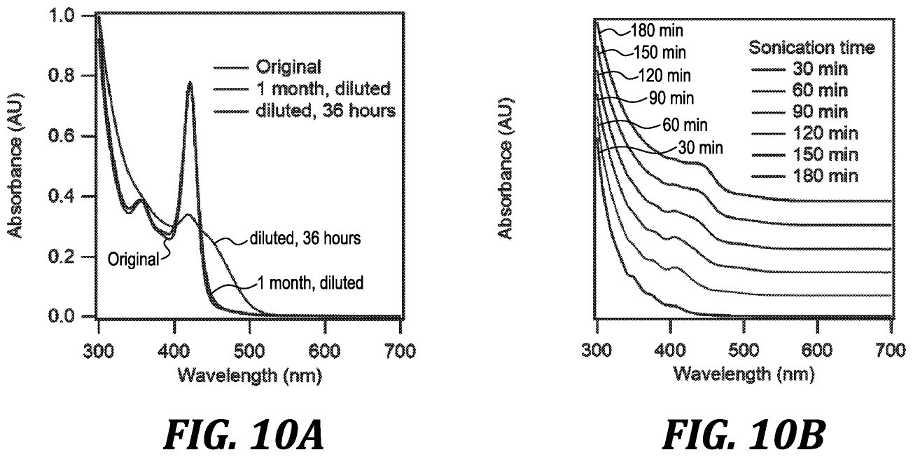

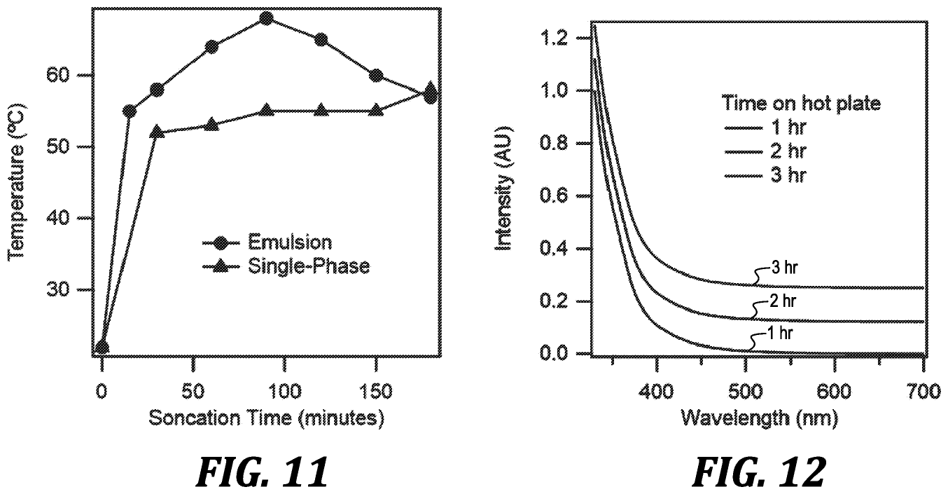

However, instability of MSCs was also evident when samples containing aggregates were diluted, which unbundled the aggregates into individual MSCs. When a diluted sample was left for 36 hours at room temperature, the sharp peak at 420 nm was almost completely quenched, and a broad peak emerged (FIG. 10A) at lower energies, indicating the formation of regular QDs. The same phenomenon was observed even with samples that were purified, indicating that these regular QDs were, at least in part, a result of Ostwald ripening. On the other hand, the stability of the MSCs when they were in an aggregated state was remarkable. If a sample was kept in its original higher concentration for a month, their UV-Vis spectra showed no apparent change.

The apparent instability of the MSCs may also explain the decrease in MSC concentration after prolonged sonication in the emulsion system (FIG. 8A). The creation of MSCs was discussed as the result of the extreme temperature and pressure exhibited by cavitation. Cavitation also evoked high velocity microjets that may dislodge MSCs from their bundles, and dislodged MSCs dissolve or grow into regular QDs. Therefore, there were two competing processes with respect to MSC concentration. Towards the beginning of the sonication process, the system was rich in molecular precursors, and the rate of MSC creation was much faster than the rate dislodging. Towards the end of the process, the dislodging of MSCs dominated due to the higher concentration of MSC aggregates and lower concentration of aggregates.

In the case of single-phase systems, the resulting ultra-small QDs actually went through MSC intermediates. Evidence of this could be found in the UV-Vis spectra of the pre-cleaned samples from the single-phase system (FIG. 10B). Multiple peaks could clearly be seen, resembling the UV-Vis spectra of smaller MSCs at earlier sonication times and Ostwald ripened MSCs in FIG. 10A at longer sonication times. Because the conversion was much slower in the single-phase system, aggregates of MSCs were not formed because their concentration was low, and hence the MSCs were not protected from growth and dissolution. Therefore, any MSCs that were formed undergo ripening very quickly, resulting in regular QDs. This contrasted with the emulsion-system where the rapid synthesis to concentrated MSCs allowed them to aggregate and stabilized before they become regular QDs.

Thus, in the present example, sonochemical synthesis of CdSe QDs was performed in a single-phase and an emulsion system, while keeping the bulk sample temperatures low (<70° C.). Conversion of precursors into QDs was much faster in emulsion systems because the liquid-liquid interface serves as heterogenous nucleation sites for bubbles which led to more frequent and more effective cavitation events to drive the reactions. In emulsion systems, MSCs, (CdSe)₃₃ and (CdSe)₃₄, were synthesized, prolonged sonication beyond 120 minutes led to the creation of regular QDs. Along with the ligands, these MSCs were stable via the formation of inorganic-organic aggregates. Unbundling of these aggregates by dilution destabilized the MSCs, resulting in dissolution and growth of MSCs into regular QDs. The formation of aggregates was made possible by the rapid rise in MSC concentration so that they could form aggregates before they turn into regular QDs. In the single-phase bulk synthesis systems, MSCs were created as intermediates to QD synthesis. However, because the reaction rate was slow, the MSC concentration was too low for them to form stable aggregates. Instead, they underwent Ostwald ripening to form regular QDs. On-demand synthesis of CdSe QDs was also demonstrated simply by turning the ultrasound ‘on’ and ‘off’ at any arbitrary rate.

The rate of QD production in the emulsion system was 3.8 g/L hr with complete conversion of precursors, which was much faster than that in the single-phase system (0.48 g/L hr) and was comparable to the typical hot-injection synthesis of QDs, and could be further optimized. Letting the temperature rise higher may speed up QD production, but this is likely at the cost of a loss in temporal reaction control. Finally, although the present Example describes CdSe QDs, there are no theoretical limitations to other types of QDs.

While illustrative embodiments have been illustrated and described, it will be appreciated that various changes can be made therein without departing from the spirit and scope of the disclosure.

1. A sonochemical method of making particles, comprising:
providing an emulsion comprising uniformly dispersed immiscible droplets in a continuous phase, and one or more particle precursors;
exposing the emulsion to ultrasound irradiation having a frequency of at least 20 kHz to nucleate and form particles in the emulsion, without increasing an emulsion bulk temperature in excess of 50° C.; and
isolating the particles from the emulsion,
wherein when the emulsion is an aqueous emulsion, the particle precursors do not comprise a gold salt.

2. The sonochemical method of claim 1, wherein the emulsion further comprises a surface stabilizer selected from polymers, surfactants, particles, and any combination thereof

3. The sonochemical method of claim 1, wherein the emulsion does not comprise an aqueous solvent.

4. The sonochemical method of claim 1, wherein the droplets comprise a solvent selected from a terpene, a fatty acid, a fatty amine, a triglyceride, an ionic liquid, a deep-eutectic solvent, an alkane, an alkene, an aromatic solvent, a silicone oil, a long-chain alcohol, or any combination thereof

5. The sonochemical method of claim 1, wherein the continuous phase of the emulsion comprises a solvent selected from water, alcohol, fatty acid, deep eutectic solvent, a polymer, an ionic liquid, an organic solvent, or any combination thereof.

6. (canceled)

7. The sonochemical method of claim 1, wherein the ultrasound irradiation provides a local temperature of 500 K or more in at least one dispersed immiscible droplet of the emulsion.

8. (canceled)

9. The sonochemical method of claim 1, wherein exposing the emulsion to ultrasound irradiation causes one of more of the particle precursors to undergo a chemical reaction to form covalent or ionic bonds to provide the particles.

10. The sonochemical method of claim 1, wherein the one or more particle precursors comprise organometallic complexes.

11. The sonochemical method of claim 1, wherein the one or more particle precursors are selected from soluble organo-chalcogenide precursor compounds, soluble organo-phosphorus precursor compounds, soluble organometallic precursor compounds.

12. The sonochemical method of claim 1, wherein the emulsion comprises two particle precursors in a molar ratio from 10:1 to 1:10.

13. The sonochemical method of claim 1, wherein the emulsion is in the form of a gel.

14. The sonochemical method of claim 1, wherein the emulsion is in the form of a liquid.

15. The sonochemical method of claim 1, wherein the method is carried out at the emulsion bulk temperature of 150° C. or less.

16. The sonochemical method of claim 1, wherein the emulsion is cycled through a predetermined region of ultrasound irradiation.

17. The sonochemical method of claim 16, wherein the emulsion is continuously cycled through the predetermined region of ultrasound irradiation.

18. The sonochemical method of claim 1, wherein exposing the emulsion to ultrasound irradiation comprises subjecting the emulsion to spatially and/or temporally controlled ultrasonic irradiation.

19. The sonochemical method of claim 1, wherein the particles comprise CdSe, InP, PbS, CdTe, CdS, PbTe, PbSe, CuS, CuSe, CuTe, ZnS, ZnSe, ZnTe, or

20. The sonochemical method of claim 1, wherein the particles comprise magic size clusters.

21. The sonochemical method of claim 1, wherein the particles have an average diameter of less than 200 nm.

22. (canceled)

23. (canceled)

24. The sonochemical method of claim 1, wherein the particles comprise quantum dots.

25. (canceled)

26. (canceled)
